(19) United States
(12) Patent Application Publication
(10) Pub. No.: US 2023/0173526 A1
(43) Pub. Date: Jun. 8, 2023

(54) HOME PORT, AND SUBSTRATE PROCESSING APPARATUS AND HOME PORT CLEANING METHOD USING THE SAME

(71) Applicant: SEMES CO., LTD., Cheonan-si (KR)

(72) Inventors: Young Jun SON, Cheonan-si (KR); Hyung Seok KANG, Suwon-si (KR); Min Woo KIM, Seoul (KR)

(73) Assignee: SEMES CO., LTD., Cheonan-si (KR)

(21) Appl. No.: 18/073,483

(22) Filed: Dec. 1, 2022

(30) Foreign Application Priority Data
Dec. 3, 2021 (KR) 10-2021-0171537

(51) Int. Cl. B05B 16/80; B05B 16/20; B08B 3/04

(52) U.S. Cl. CPC B05B 16/80; B05B 16/20; B08B 3/047

(57) ABSTRACT

Proposed are a home port, and a substrate processing apparatus and a home port cleaning method using the same. The home port includes a housing supported by a holder and having a space therein, a nozzle holder provided at an upper portion of the housing and mounting a nozzle for discharging a process liquid to a substrate, an inclined surface formed below the nozzle holder in the space, an exhaust hole exhausting fumes generated in the space of the housing, a rinse supply hole supplying a rinse liquid for removing a residual process liquid remaining on the inclined surface, a hinge provided at a lower portion of the housing and hingedly coupling the housing and the holder to enable rotation of the housing, and an actuating means rotating the housing in a direction in which the inclined surface is parallel to a ground surface on which the housing is installed.

### CROSS REFERENCE TO RELATED APPLICATION

The present application claims priority to Korean Patent Application No. 10-2021-0171537, filed Dec. 3, 2021, the entire contents of which is incorporated by reference herein for all purposes.

### BACKGROUND OF THE INVENTION

### Field of the Invention

The present disclosure relates to a home port, and a substrate processing apparatus and a home port cleaning method using the same.

### Description of the Related Art

Photolithography, which is a part of a semiconductor fabrication process, is a process of forming a desired pattern on a wafer. The photolithography process is performed by a substrate processing apparatus that continuously performs coating, exposure, and development.

Meanwhile, the substrate processing apparatus includes a home port. The home port includes a holder for mounting a nozzle that discharges a coating liquid or a developer to a wafer during a coating process or a developing process, and a receiving space for accommodating a process liquid (liquid necessary for the process, such as coating liquid or developer), which is periodically discharged, in order to prevent contamination of the process liquid. In addition, the home port also includes an exhaust hole for discharging fumes generated from the process liquid discharged from the nozzle and a cleaning liquid supplying means for cleaning the discharged process liquid.

FIG. 1 a sectional view illustrating an example of a home port. A nozzle holder 20 is installed at an upper portion of a housing 10, and a space 30 is formed inside the housing 10. The space 30 has an inclined surface 40 on which a process liquid 2 discharged from a nozzle 1 falls so that the discharged process liquid moves to the bottom of the space 30 along the inclined surface 40. When the process liquid 2 discharged to the inclined surface 40 remains on the inclined surface 40 and forms a residual process liquid 3, as illustrated in FIG. 3, there is a need to clean the residual process liquid 3 with a rinse liquid 4.

In the conventional home port, the rinse liquid 4 is supplied to flow over the residual process liquid 3. In this case, a large amount of the rinse liquid 4 needs to be used to completely remove the residual process liquid 3. As the rinse liquid 4, an organic solvent commonly called a thinner is used. However, since the thinner is an environmental pollutant, an increase in the amount of the thinner results in a proportional increase in in the cost of disposal.

The foregoing is intended merely to aid in the understanding of the background of the present disclosure, and is not intended to mean that the present disclosure falls within the purview of the related art that is already known to those skilled in the art.

### SUMMARY OF THE INVENTION

Accordingly, the present disclosure has been made keeping in mind the above problems occurring in the related art, and an objective of the present disclosure is to provide a home port capable of efficiently cleaning a residual process liquid in the home port while minimizing the amount of rinse liquid used for cleaning the residual process liquid, and a home port cleaning method using the same.

In order to achieve the above objective, according to one aspect of the present disclosure, there is provided a home port including: a housing supported by a holder and having a space therein; a nozzle holder provided at an upper portion of the housing and configured to mount a nozzle configured to discharge a process liquid to a substrate; an inclined surface formed below the nozzle holder in the space; an exhaust hole configured to exhaust fumes generated in the space of the housing; a rinse supply hole configured to supply a rinse liquid for removing a residual process liquid remaining on the inclined surface after the process liquid is discharged from the nozzle mounted on the nozzle holder; a hinge provided at a lower portion of the housing and hingedly coupling the housing and the holder to enable rotation of the housing; and an actuating means configured to rotate the housing in a direction in which the inclined surface is parallel to a ground surface on which the housing is installed.

The hinge may be installed at a position where the housing can be sufficiently rotated to allow the residual process liquid to be immersed in the rinse liquid.

The actuating means may include: a wire having a first end coupled to the housing at a position above the hinge; and a winch connected to a second end of the wire. Alternatively, the actuating means may include: a motor configured to rotate the housing; and a reduction gear configured to transmit a rotational force of the motor to the housing. Alternatively, the actuating means may be a hydraulic cylinder including a rod rotatably coupled to the housing.

The home port may further include a rotation limiter configured to limit rotation of the housing. The rotation limiter may have a limiting surface contacting the housing.

The rinse liquid may be a thinner.

According to another aspect of the present disclosure, there is provided a substrate processing apparatus having the above-described home port.

According to still another aspect of the present disclosure, there is provided a home port cleaning method including: a preparation step of preparing the above-described home port; a rotating step of rotating the housing in the direction in which the inclined surface is parallel to the ground surface; a rinse liquid supply step of supplying the rinse liquid toward the inclined surface of the housing through the rinse supply hole in a state in which the housing is rotated; a cleaning step of maintaining a state in which the residual process liquid remaining on the inclined surface is immersed in the rinse liquid supplied in the rinse liquid supply step; and a discharge step of discharging the rinse liquid.

According to the present disclosure, it is possible to provide a home port capable of efficiently cleaning a residual process liquid remaining in the home port while minimizing the amount of rinse liquid which employs a thinner, and provide a substrate processing apparatus and a home port cleaning method using the same.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating an example of a conventional home port;

FIG. 2 is a view illustrating that a process liquid is discharged from a nozzle mounted on the home port illustrated in FIG. 1;

FIG. 3 is a view illustrating that a residual process liquid in the home port illustrated in FIG. 1 is cleaned with a rinse liquid;

FIG. 4 is a view illustrating a home port according to a first embodiment of the present disclosure;

FIG. 5 is a view illustrating a state in which a residual process liquid is immersed in a rinse liquid by supplying the rinse liquid while the home port illustrated in FIG. 4 is rotated;

FIG. 6 is a view illustrating a home port according to a second embodiment of the present disclosure; and

FIGS. 7 and 8 are views illustrating a home port according to a third embodiment of the present disclosure.

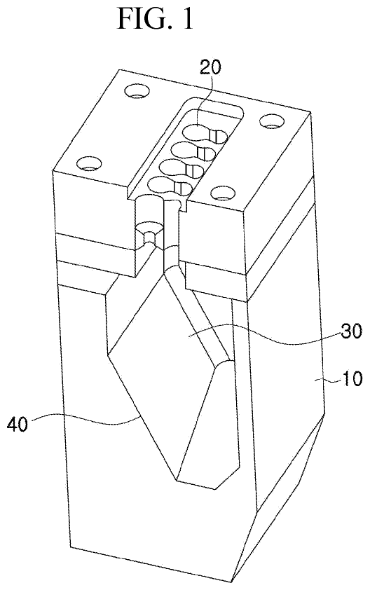

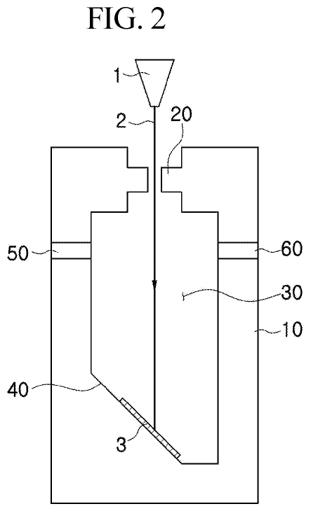

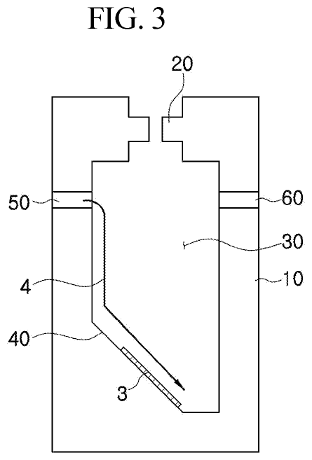

### DETAILED DESCRIPTION OF THE INVENTION

Hereinafter, exemplary embodiments of the present disclosure will be described with reference to the drawings to provide specific contents for practicing the present disclosure.

First, a home port according to a first embodiment, which is a first aspect of the present disclosure, will be described.

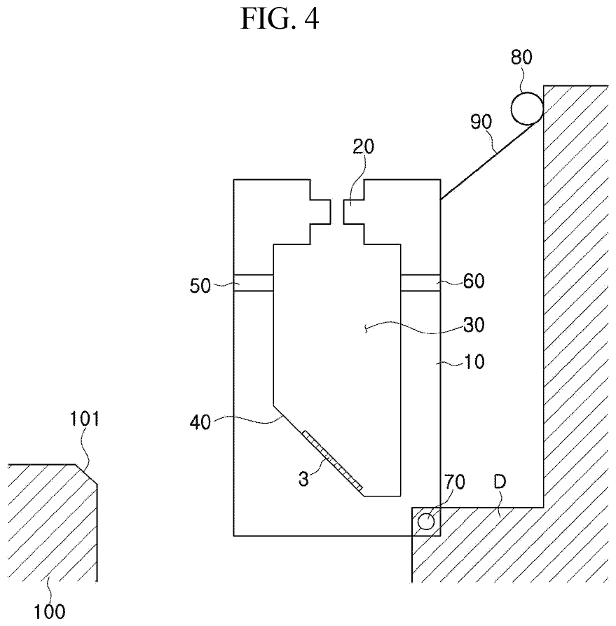

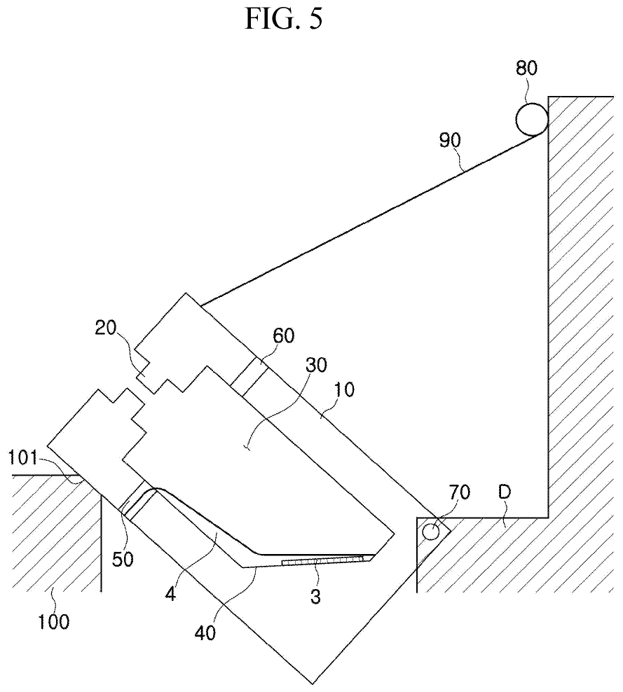

FIG. 4 is a view illustrating the home port according to the first embodiment of the present disclosure. FIG. 5 is a view illustrating a state in which a residual process liquid 3 is immersed in a rinse liquid 4 by supplying the rinse liquid while the home port illustrated in FIG. 4 is rotated.

The home port according to this embodiment includes a housing 10, a nozzle holder 20, an inclined surface 40, an exhaust hole 50, a rinse supply hole 60, a hinge 70, a actuating means, and a rotation limiter 100.

The housing 10 is supported by a holder D, and has a space 30 formed therein.

The holder D may be configured in any suitable manner as long as it can support the housing 10 to a degree that it can be rotated sufficiently as will be described later. In order to support the housing 10 to be able to be rotated properly, it is preferable that the holder D includes a surface located at a predetermined height from the ground surface as illustrated in FIG. 4.

The nozzle holder 20 is a configuration for mounting a nozzle. The nozzle is a configuration for discharging a process liquid to a substrate, and is temporarily mounted on the nozzle holder 20 when the process liquid is not discharged to the substrate. The nozzle holder 20 is a configuration for this purpose.

As described in the description of the related art, the process liquid is defined as a generic tam for liquids necessary for semiconductor processes, such as a coating liquid, a photosensitive liquid, and a developer.

As illustrated in FIG. 4, the inclined surface 40 is an inclined surface formed below the nozzle holder 20 in the space 30. The process liquid accommodated in the nozzle mounted on the nozzle holder 20 may be contaminated when it is exposed to air, so the process liquid is periodically discharged from the nozzle. At this time, the discharged process liquid moves to the bottom of the space 30 along the inclined surface 40.

Fumes are generated in the space 30 as a result of the periodic discharge of the process liquid from the nozzle. The exhaust hole 50 is a through-hole formed in the housing 10 to exhaust the fumes.

The rinse supply hole 60 is a through-hole formed in the housing 10 to supply the rinse liquid 4 for removing the residual process liquid 3 remaining on the inclined surface 40 after the process liquid is discharged from the nozzle mounted on the nozzle holder 20. The residual process liquid 3 refers to a process liquid that is adhered to the inclined surface 40 without moving to the bottom of the space 30 along the inclined surface 40 due to viscosity of the process liquid. In the drawings, the residual process liquid 3 is illustrated in a solid form having a predetermined height and area for convenience of the drawings. However, it may be in the form of droplets, or in the form of a combination of a solid having a relatively large area and droplets.

The rinse liquid 4 flows into the space 30 of the housing 10 through the rinse supply hole 60 to remove the residual process liquid 3.

The hinge 70 is a configuration provided at a lower portion of the housing 10 and hingedly coupling the housing 10 and the holder D to enable the rotation of the housing 10.

The hinge 70 is installed at a position where the housing 10 can be sufficiently rotated to allow the residual process liquid 3 to be immersed in the rinse liquid 4. In this embodiment, the hinge 70 is installed at the lower portion of the housing 10 on the opposite side of the inclined surface 40, and hingedly couples the housing 10 and a corner portion of the holder D.

The actuating means is a configuration for rotating the housing 10 in a direction in which the inclined surface 40 is parallel to the ground surface on which the housing 10 is installed. In this embodiment, the actuating means includes a wire 80 and a winch 90.

The wire 80 is a configuration having a first end coupled to the housing 10 and a second end coupled to the winch 90. As the wire 80, a steel wire may be used.

The winch 90 is a configuration for winding or unwinding the wire 80. In this embodiment, the winch 90 moves the housing 10 so that when the wire 80 is unwound in the state illustrated in FIG. 4, the housing 10 is rotated by gravity to the state illustrated in FIG. 5, and when the wire 80 is wound in a state in which the cleaning is completed, the housing 10 returns to the state illustrated in FIG. 4.

The rotation limiter 100 is a configuration for limiting the rotation of the housing 10 so as not to be rotated by equal to or greater than a predetermined angle. As illustrated in FIG. 4, the rotation limiter 100 may be manufactured in a shape similar to that of the holder D, and may have a limiting surface 101 contacting the housing 10.

Hereinafter, a home port according to a second embodiment of the present disclosure will be described.

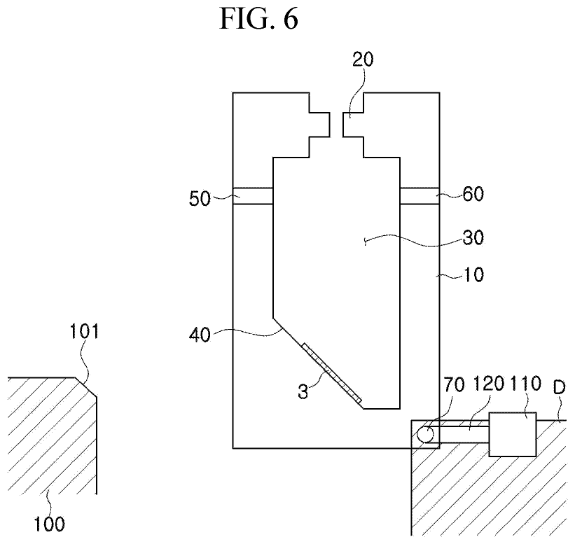

FIG. 6 is a view illustrating the home port according to the second embodiment of the present disclosure.

The home port according to this embodiment includes a housing 10, a nozzle holder 20, an inclined surface 40, an exhaust hole 50, a rinse supply hole 60, a hinge 70, an actuating means, and a rotation limiter 100.

The housing 10 is supported by a holder D, and has a space 30 formed therein.

The holder D may be configured in any suitable manner as long as it can support the housing 10 to a degree that it can be rotated sufficiently as will be described later. In order to support the housing 10 to be able to be rotated properly, it is preferable that the holder D includes a surface located at a predetermined height from the ground surface as illustrated in FIG. 6.

The nozzle holder 20 is a configuration for mounting a nozzle. The nozzle is a configuration for discharging a process liquid to a substrate, and is temporarily mounted on the nozzle holder 20 when the process liquid is not discharged to the substrate. The nozzle holder 20 is a configuration for this purpose.

As described in the description of the related art, the process liquid is defined as a generic term for liquids necessary for semiconductor processes, such as a coating liquid, a photosensitive liquid, and a developer.

As illustrated in FIG. 6, the inclined surface 40 is an inclined surface formed below the nozzle holder 20 in the space 30. The process liquid accommodated in the nozzle mounted on the nozzle holder 20 may be contaminated when it is exposed to air, so the process liquid is periodically discharged from the nozzle. At this time, the discharged process liquid moves to the bottom of the space 30 along the inclined surface 40.

Fumes are generated in the space 30 as a result of the periodic discharge of the process liquid from the nozzle. The exhaust hole 50 is a through-hole formed in the housing 10 to exhaust the fumes.

The rinse supply hole 60 is a through-hole formed in the housing 10 to supply the rinse liquid 4 for removing the residual process liquid 3 remaining on the inclined surface 40 after the process liquid is discharged from the nozzle mounted on the nozzle holder 20. The residual process liquid 3 refers to a process liquid that is adhered to the inclined surface 40 without moving to the bottom of the space 30 along the inclined surface 40 due to viscosity of the process liquid. In the drawings, the residual process liquid 3 is illustrated in a solid form having a predetermined height and area for convenience of the drawings. However, it may be in the form of droplets, or in the form of a combination of a solid having a relatively large area and droplets.

The rinse liquid 4 flows into the space 30 of the housing 10 through the rinse supply hole 60 to remove the residual process liquid 3.

The hinge 70 is a configuration provided at a lower portion of the housing 10 and hingedly coupling the housing 10 and the holder D to enable the rotation of the housing 10.

The hinge 70 is installed at a position where the housing 10 can be sufficiently rotated to allow the residual process liquid 3 to be immersed in the rinse liquid 4. In this embodiment, the hinge 70 is installed at the lower portion of the housing 10 on the opposite side of the inclined surface 40, and hingedly couples the housing 10 and a corner portion of the holder D.

The actuating means is a configuration for rotating the housing 10 in a direction in which the inclined surface 40 is parallel to the ground surface on which the housing 10 is installed. In this embodiment, the actuating means includes a motor 110 and a reduction gear 120.

A driving force of the motor 110 is transmitted to the housing 10 through the reduction gear 120 to actuate the housing 10.

The motor 110 is manufactured to provide an appropriate torque suitable for the weight of the housing 10.

The state in which the housing 10 is rotated by the motor 110 remains substantially the same as that illustrated in FIG. 5 and thus is not separately illustrated in the drawings.

The rotation limiter 100 is a configuration for limiting the rotation of the housing 10 so as not to be rotated by equal to or greater than a predetermined angle. As illustrated in FIG. 6, the rotation limiter 100 may be manufactured in a shape similar to that of the holder D, and may have a limiting surface 101 contacting the housing 10.

Hereinafter, a home port according to a third embodiment of the present disclosure will be described.

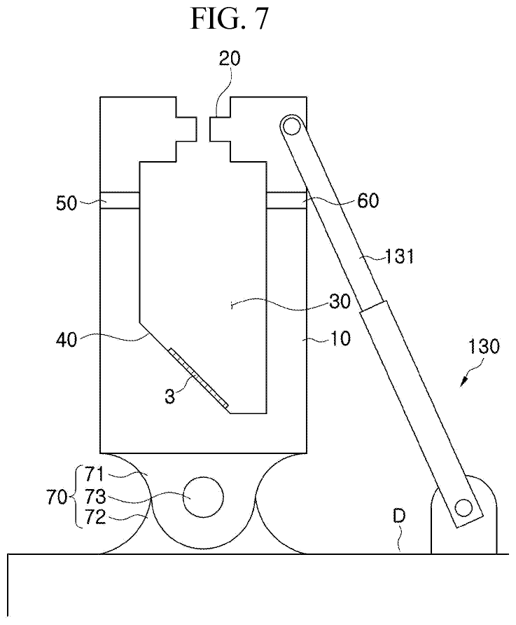

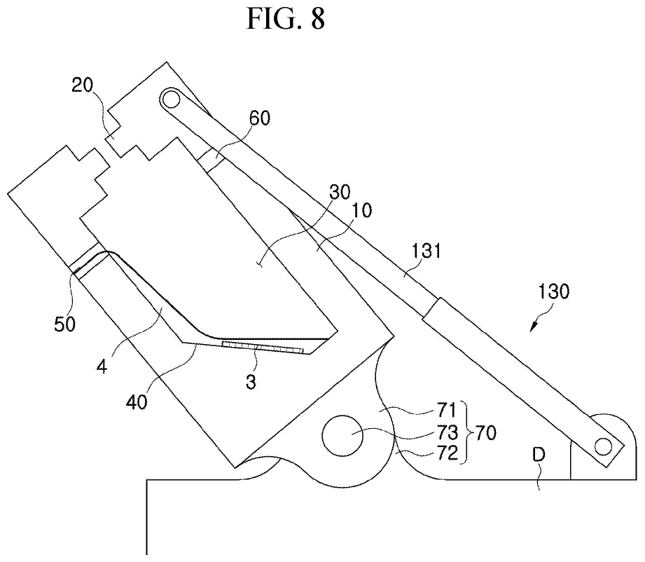

FIGS. 7 and 8 are views illustrating the home port according to the third embodiment of the present disclosure.

The home port according to this embodiment includes a housing 10, a nozzle holder 20, an inclined surface 40, an exhaust hole 50, a rinse supply hole 60, a hinge 70, and an actuating means.

The housing 10 is supported by a holder D, and has a space 30 formed therein.

The holder D may be configured in any suitable manner as long as it can support the housing 10 to a degree that it can be rotated sufficiently as will be described later. In order to support the housing 10 to be able to be rotated properly, it is preferable that the holder D includes a surface located at a predetermined height from the ground surface as illustrated in FIG. 7.

The nozzle holder 20 is a configuration for mounting a nozzle. The nozzle is a configuration for discharging a process liquid to a substrate, and is temporarily mounted on the nozzle holder 20 when the process liquid is not discharged to the substrate. The nozzle holder 20 is a configuration for this purpose.

As described in the description of the related art, the process liquid is defined as a generic term for liquids necessary for semiconductor processes, such as a coating liquid, a photosensitive liquid, and a developer.

As illustrated in FIG. 7, the inclined surface 40 is an inclined surface formed below the nozzle holder 20 in the space 30. The process liquid accommodated in the nozzle mounted on the nozzle holder 20 may be contaminated when it is exposed to air, so the process liquid is periodically discharged from the nozzle. At this time, the discharged process liquid moves to the bottom of the space 30 along the inclined surface 40.

Fumes are generated in the space 30 as a result of the periodic discharge of the process liquid from the nozzle. The exhaust hole 50 is a through-hole formed in the housing 10 to exhaust the fumes.

The rinse supply hole 60 is a through-hole formed in the housing 10 to supply the rinse liquid 4 for removing the residual process liquid 3 remaining on the inclined surface 40 after the process liquid is discharged from the nozzle mounted on the nozzle holder 20. The residual process liquid 3 refers to a process liquid that is adhered to the inclined surface 40 without moving to the bottom of the space 30 along the inclined surface 40 due to viscosity of the process liquid. In the drawings, the residual process liquid 3 is illustrated in a solid form having a predetermined height and area for convenience of the drawings. However, it may be in the form of droplets, or in the form of a combination of a solid having a relatively large area and droplets.

The rinse liquid 4 flows into the space 30 of the housing 10 through the rinse supply hole 60 to remove the residual process liquid 3.

The hinge 70 is a configuration provided at a lower portion of the housing 10 and hingedly coupling the housing 10 and the holder D to enable the rotation of the housing 10.

The hinge 70 is installed at a position where the housing 10 can be sufficiently rotated to allow the residual process liquid 3 to be immersed in the rinse liquid 4. In this embodiment, the hinge 70 is installed in the center of a lower portion of the housing 10.

The hinge 70 includes a first member 71 coupled to the lower portion of the housing 10, a second member 72 installed on an upper surface of the holder D, and a hinge pin 73 passing through the first member 71 and the second member 72.

The actuating means is a configuration for rotating the housing 10 in a direction in which the inclined surface 40 is parallel to the ground surface on which the housing 10 is installed. In this embodiment, the actuating means is a hydraulic cylinder 130.

As illustrated, a rod 131 of the hydraulic cylinder 130 is rotatably coupled to the housing 10, and the hydraulic cylinder 130 is rotatably coupled to the holder D.

When the hydraulic cylinder 130 is used as the actuating means, it is not necessary to rotate the housing 10 by gravity unlike the wire 80 or the winch 90 illustrated in FIG. 4. This eliminates the need for installing the hinge 70 at a corner portion of the holder D, and eliminates the need for providing a rotation limiter.

Hereinafter, as a second aspect of the present disclosure, a home port cleaning method using each of the above-described home ports will be described.

The home port cleaning method according to the present embodiment includes a preparation step, a rotating step, a rinse liquid supply step, a cleaning step, and a discharge step.

The preparation step is a step of preparing each of the above-described home ports (illustrated in FIGS. 4 to 7).

The rotating step is a step of rotating the housing 10 in a direction in which the inclined surface 40 is parallel to the ground surface in order to clean the above-described home port. Performing the rotating step means that cleaning is required, that is, more than a predetermined amount of residual process liquid 3 remains on the inclined surface 40.

The housing 10 is rotated by the actuating means. In the case of the home port illustrated in FIG. 4, when the winch 90 unwinds the wire 80, the housing 10 is rotated by gravity. In the case of the home port illustrated in FIG. 6, the housing 10 is rotated by a driving force of the motor 110. In the case of the home port illustrated in FIG. 7, the housing 10 is rotated by a pressing force applied to the housing 10 as the rod 131 of the hydraulic cylinder 130 is moved.

The state in which the housing 10 is rotated through the rotating step is illustrated in FIGS. 5 and 8.

The rinse liquid supply step is a step of supplying the rinse liquid 4 through the rinse supply hole 60 in the state in which the housing 10 is rotated.

The cleaning step is a step of cleaning the space 30 by maintaining a state in which the residual process liquid 3 remaining on the inclined surface 40 is immersed in the rinse liquid 4 for a predetermined period of time.

The discharge step is a step of discharging the residual process liquid 3 cleaned by the rinse liquid together with the rinse liquid 4 after the cleaning step is completed.

The last aspect of the present disclosure is a substrate processing apparatus, which is characterized by including each of the above-described home ports. Since the home port has been sufficiently described above, further description thereof will be omitted.

While specific contents for practicing the present disclosure have been provided above by describing some aspects of the present disclosure and embodiments according to the aspects, the spirit and scope of the present disclosure are not limited to the embodiments and various changes and modifications are possible without departing from the spirit and scope of the present disclosure.

What is claimed is:

1. A home port comprising:
a housing supported by a holder and having a space therein;
a nozzle holder provided at an upper portion of the housing and configured to mount a nozzle configured to discharge a process liquid to a substrate;
an inclined surface formed below the nozzle holder in the space;
an exhaust hole configured to exhaust fumes generated in the space of the housing;
a rinse supply hole configured to supply a rinse liquid for removing a residual process liquid remaining on the inclined surface after the process liquid is discharged from the nozzle mounted on the nozzle holder;
a hinge provided at a lower portion of the housing and hingedly coupling the housing and the holder to enable rotation of the housing; and
an actuating means configured to rotate the housing in a direction in which the inclined surface is parallel to a ground surface on which the housing is installed.

2. The home port of claim 1, wherein the hinge is installed at a position where the housing can be sufficiently rotated to allow the residual process liquid to be immersed in the rinse liquid.

3. The home port of claim 1, wherein the actuating means comprises:
a wire having a first end coupled to the housing at a position above the hinge; and
a winch connected to a second end of the wire.

4. The home port of claim 1, wherein the actuating means comprises:
a motor configured to rotate the housing; and
a reduction gear configured to transmit a rotational force of the motor to the housing.

5. The home port of claim 1, wherein the actuating means is a hydraulic cylinder comprising a rod rotatably coupled to the housing.

6. The home port of claim 3, further comprising a rotation limiter configured to limit rotation of the housing.

7. The home port of claim 4, further comprising a rotation limiter configured to limit rotation of the housing.

8. The home port of claim 6, wherein the rotation limiter has a limiting surface contacting the housing.

9. The home port of claim 1, wherein the rinse liquid is a thinner.

10. A substrate processing apparatus having a home port, the home port comprising:
a housing supported by a holder and having a space therein;
a nozzle holder provided at an upper portion of the housing and configured to mount a nozzle configured to discharge a process liquid to a substrate;
an inclined surface formed below the nozzle holder in the space;
an exhaust hole configured to exhaust fumes generated in the space of the housing;
a rinse supply hole configured to supply a rinse liquid for removing a residual process liquid remaining on the inclined surface after the process liquid is discharged from the nozzle mounted on the nozzle holder;
a hinge provided at a lower portion of the housing on an opposite side of the inclined surface, and hingedly coupling the housing and the holder; and
an actuating means configured to rotate the housing in a direction in which the inclined surface is parallel to a ground surface on which the housing is installed.

11. The substrate processing apparatus of claim 10, wherein the hinge is installed at a position where the housing can be sufficiently rotated to allow the residual process liquid to be immersed in the rinse liquid.

12. The substrate processing apparatus of claim 10, wherein the actuating means comprises:
a wire having a first end coupled to the housing at a position above the hinge; and
a winch connected to a second end of the wire.

13. The substrate processing apparatus of claim 10, wherein the actuating means comprises:
a motor configured to rotate the housing; and
a reduction gear configured to transmit a rotational force of the motor to the housing.

14. The substrate processing apparatus of claim 10, wherein the actuating means is a hydraulic cylinder comprising a rod rotatably coupled to the housing.

15. The substrate processing apparatus of claim 12, further comprising a rotation limiter configured to limit rotation of the housing.

16. The substrate processing apparatus of claim 13, further comprising a rotation limiter configured to limit rotation of the housing.

17. The substrate processing apparatus of claim 15, wherein the rotation limiter has a limiting surface contacting the housing.

18. The substrate processing apparatus of claim 10, wherein the rinse liquid is a thinner.

19. A home port cleaning method comprising:
a preparation step of preparing the home port according to claim 1;
a rotating step of rotating the housing in the direction in which the inclined surface is parallel to the ground surface;
a rinse liquid supply step of supplying the rinse liquid toward the inclined surface of the housing through the rinse supply hole in a state in which the housing is rotated;
a cleaning step of maintaining a state in which the residual process liquid remaining on the inclined surface is immersed in the rinse liquid supplied in the rinse liquid supply step; and
a discharge step of discharging the rinse liquid.

20. The home port cleaning method of claim 19, wherein the rinse liquid is a thinner.
